(19) United States
(12) Patent Application Publication
(10) Pub. No.: US 2026/0338874 A1
(43) Pub. Date: Oct. 29, 2026

(54) Method And Circuit Arrangement For Monitoring A Battery Cell

(71) Applicant: Schaeffler Technologies AG & Co. KG, Herzogenaurach (DE)

(72) Inventor: Christian Reichinger, Neutraubling (DE)

(73) Assignee: Schaeffler Technologies AG & Co. KG, Herzogenaurach (DE)

(21) Appl. No.: 19/119,595

(22) PCT Filed: Oct. 9, 2023
(86) PCT No.: PCT/EP2023/077901

§ 371 Date: Apr. 9, 2025

(30) Foreign Application Priority Data
Oct. 11, 2022 (DE) 10 2022 210 730.6

(51) Int. Cl. G01R 31/396; G01R 19/165; G01R 31/378; G01R 31/3835; H01M 10/42

(52) U.S. Cl. CPC G01R 31/396; G01R 19/1659; G01R 31/378; G01R 31/3835; H01M 10/4285

(57) ABSTRACT

An example method includes: receiving a cell voltage with a circuit having a main monitoring channel and a redundant channel; using a first ADC to provide a first output signal and the second ADC to provide a second output signal; determining a comparison signal; if the first output signal is below a specified first voltage value and exceeds a specified second voltage value, comparing the comparison signal to a specified first trigger threshold and, if the comparison signal exceeds the first trigger, providing a first error; and, if the first output signal is equal to or greater than the specified first value or equal to or less than the second specified value, comparing the comparison signal to a second trigger and, if greater, providing a second error signal. The first voltage value is greater than the second and the first trigger threshold has a greater magnitude than the second.

### CROSS-REFERENCE TO RELATED APPLICATIONS

This application a U.S. National Stage Application of International Application No. PCT/EP2023/077901 filed Oct. 9, 2023, which designates the United States of America, and claims priority to DE Application No. 10 2022 210 730.6 filed Oct. 11, 2022, the contents of which are hereby incorporated by reference in their entirety.

### TECHNICAL FIELD

The present disclosure relates to rechargeable batteries. Various embodiments of the teachings herein include methods and/or circuit arrangements for monitoring a rechargeable battery cell.

### BACKGROUND

A rechargeable battery cell may be arranged in a rechargeable battery, in particular in a rechargeable traction battery of an electric vehicle. With electrification of the drivetrain, ever-increasing accuracy requirements are being placed on battery monitoring in order to improve the range and operational safety of electric vehicles, for example hybrid vehicles (HEV), plug-in hybrid vehicles (PHEV) and fully electric vehicles (BEV). An important point here is the measurement accuracy for cell voltage monitoring.

A high Automotive Safety Integrity Level (ASIL) in class C or D calls for the cell voltage to be available as a measured value with high accuracy, even in the event of undetected errors. With higher cell voltage measurement accuracy, the traction battery can be operated closer to the cell voltage limits without risk, increasing the achievable range with the same battery capacity. In recent years, the performance of the semiconductor devices used for carrying out battery monitoring has already improved significantly. However, due to the high safety requirements, the measuring circuits, for example the analog-to-digital converters for converting the recorded voltage sensor signals, must be partially redundant. The voltage sensor signals are compared. When measuring the cell voltage, unavoidable disturbing influences, so-called ripple disturbances, occur.

A trigger threshold for signaling an error in the battery monitoring circuit is preferably defined such that these permissible ripple disturbances are not interpreted in the battery monitoring circuit as errors. In the worst case, exceedance of the trigger threshold initiates an emergency stop for the drivetrain, but at least an incrementation of the service life counter of the traction battery.

Due to real tolerances in components of the filter structures upstream of the two ADCs, it is not possible to completely filter out or suppress the ripple disturbance. The remaining maximum ripple disturbances thus determine the range of a battery, as the trigger threshold must be set correspondingly high. A high trigger threshold requires e.g. the battery charging process to be curtailed earlier, and the battery is not fully charged.

### SUMMARY

The teachings of the present disclosure provide methods and circuit arrangements for monitoring a rechargeable battery cell that contribute to increasing an achievable range of a vehicle with a specific battery capacity. For example, some embodiments of the teachings herein include a method for monitoring a rechargeable battery cell of a rechargeable battery, in which a first measurement signal that is representative of a cell voltage of the rechargeable battery cell is received by a circuit arrangement (10) comprising a main monitoring channel (20) and a redundant monitoring channel (30), the first measurement signal is supplied to a main monitoring channel (20), which comprises a first analog-to-digital converter (24), ADC, and to a redundant monitoring channel (30), which comprises a second ADC (34), the first ADC (24) performs an analog-to-digital conversion of the first measurement signal and provides a first output signal (U_MAIN) that is representative of a cell voltage of the rechargeable battery cell, the second ADC (34) performs an analog-to-digital conversion of a signal comprising the first measurement signal and provides a second output signal (U AUX), a comparison signal is determined on the basis of the first output signal (U_MAIN) of the main monitoring channel (20) and the second output signal (U_AUX) of the redundant monitoring channel (30), if the first output signal (U_MAIN) subceeds a specified first voltage value and exceeds a specified second voltage value, the comparison signal is compared with a specified first trigger threshold (TH1) and, if the comparison signal is greater than the first trigger threshold (TH1), a first error signal (ERR1) is provided for an evaluation unit (50), and, if the first output signal (U_MAIN) is equal to or greater than the specified first voltage value or equal to or less than the second specified voltage value, the comparison signal is compared with a second specified trigger threshold (TH2) and, if the comparison signal is greater than the second trigger threshold (TH2), a second error signal (ERR2) is provided for the evaluation unit (50), wherein the first voltage value is greater than the second voltage value and the first trigger threshold (TH1) has a greater magnitude than the second trigger threshold (TH2).

In some embodiments, the first specified voltage value corresponds to a critical upper cell voltage value minus a safety margin voltage value and the second specified voltage value corresponds to a critical lower cell voltage value plus a safety margin voltage value.

In some embodiments, a direction of the current flowing into the rechargeable battery cell is taken as a basis for suppressing or ignoring the second error signal (ERR2).

In some embodiments, the signal is identical to the first measurement signal, and the second output signal (U_AUX) is representative of the cell voltage of the rechargeable battery cell.

In some embodiments, the first ADC (24) of the main monitoring channel (20) and the second ADC (34) of the redundant monitoring channel (30) use an identical reference voltage, provided by a reference voltage source used by both ADCs (24, 34), for a respective analog-to-digital conversion, the signal comprises a differential signal that is representative of a difference between a supply voltage of the second ADC (34) or the reference voltage and the provided first measurement signal, and the second output signal (U_AUX) is representative of a level-shifted cell voltage signal, and the determination of the comparison signal on the basis of the first output signal (U_MAIN) and the second output signal (U_AUX) comprises adding the first output signal (U_MAIN) and the second output signal and, if the level shift of the cell voltage signal is produced by means of the supply voltage, subtracting a setpoint value of the supply voltage of the second ADC (34), and, if the level shift of the cell voltage signal is produced by means of the reference voltage, subtracting the reference voltage.

As another example, some embodiments include a circuit arrangement (10) for monitoring a rechargeable battery cell of a rechargeable battery, wherein the circuit arrangement (10) comprises a main monitoring channel (20) containing a first analog-to-digital converter, ADC, (24) and a redundant monitoring channel (30) containing a second ADC (34), and the circuit arrangement (10) has an associated comparison unit (40) or the circuit arrangement (10) comprises the comparison unit (40), the circuit arrangement (10) is designed to receive a first measurement signal that is representative of a cell voltage of the rechargeable battery cell and to make said signal available to the main monitoring channel (20) and the redundant monitoring channel (30), the first ADC (24) is designed to perform an analog-to-digital conversion of the first measurement signal and to provide a first output signal (U_MAIN) that is representative of a cell voltage of the rechargeable battery cell, the second ADC is designed to perform an analog-to-digital conversion of a signal comprising the first measurement signal and to provide a second output signal (U_AUX), the comparison unit (40) is designed to determine a comparison signal on the basis of the first output signal (U_MAIN) of the main monitoring channel (20) and the second output signal (U_AUX) of the redundant monitoring channel (30), the comparison unit (40) is designed so as, if the first output signal (U_MAIN) subceeds a specified first voltage value and exceeds a specified second voltage value, to compare the comparison signal with a specified first trigger threshold (TH1) and, if the comparison signal is greater than the first trigger threshold (TH1), to provide a first error signal (ERR1) for an evaluation unit (50), and, if the first output signal (U_MAIN) is equal to or greater than the specified first voltage value or equal to or less than the second specified voltage value, to compare the comparison signal with a second specified trigger threshold (TH2) and, if the comparison signal is greater than the second trigger threshold (TH2), to provide a second error signal (ERR2) for the evaluation unit (50), wherein the first voltage value is greater than the second voltage value and the first trigger threshold (TH1) has a greater magnitude than the second trigger threshold (TH2).

In some embodiments, the comparison unit (40) is designed to take a provided current measurement signal that is representative of a direction of the current flowing into the rechargeable battery cell as a basis for suppressing output of the second error signal (ERR2).

In some embodiments, the signal is identical to the first measurement signal, and the second output signal (U_AUX) is representative of the cell voltage of the rechargeable battery cell.

In some embodiments, the first adc (24) of the main monitoring channel (20) and the second ADC (34) of the redundant monitoring channel (30) are designed to use an identical reference voltage, provided by a reference voltage source, for a respective analog-to-digital conversion, the signal comprises a differential signal that is representative of a difference between a supply voltage of the second ADC (34) or a reference voltage and the provided first measurement signal, and the determination of the comparison signal on the basis of the first output signal (U_MAIN) and the second output signal (U_AUX) comprises adding the first output signal (U_MAIN) and the second output signal (U_AUX) and, if the level shift of the cell voltage signal is produced by means of the supply voltage, subtracting a setpoint value of the supply voltage of the second ADC (34), and, if the level shift of the cell voltage signal is produced by means of the reference voltage, subtracting the reference voltage.

As another example, some embodiments include a monitoring system for a rechargeable battery cell, wherein the monitoring system comprises a circuit arrangement (10) as claimed in one of claims 6 to 9 and a control unit designed to take a digital measurement signal that is provided by the circuit arrangement (10) and representative of a present cell voltage of the rechargeable battery cell as a basis for specifying for the comparison unit (40) the first trigger threshold (TH1) if the digital cell voltage signal (UC) subceeds the specified first voltage value and exceeds the second voltage value, and the second trigger threshold (TH2) if the digital cell voltage signal (UC) is equal to or greater than the specified first voltage value and the second trigger threshold (TH2) if the digital cell voltage signal (UC) is equal to or less than the specified second voltage value.

As another example, some embodiments include a rechargeable battery system comprising: a rechargeable battery containing at least one rechargeable battery cell, for each of all or at least some of the rechargeable battery cells a circuit arrangement (10) as described herein and a control unit designed to take a digital cell voltage signal (UC) that is provided by the respective circuit arrangement (10) and representative of a present cell voltage of the respective rechargeable battery cell as a basis for specifying for the comparison unit (40) of the respective circuit arrangement (10) the first trigger threshold (TH1) if the digital cell voltage signal (UC) subceeds the specified first voltage value and exceeds the second voltage value and the second trigger threshold (TH2) if the digital cell voltage signal (UC) is equal to or greater than the specified first voltage value, and the second trigger threshold (TH2) if the digital cell voltage signal (UC) is equal to or less than the specified second voltage value.

As another example, some embodiments include a vehicle comprising a rechargeable battery system as described herein.

### BRIEF DESCRIPTION OF THE DRAWINGS

Exemplary embodiments of the teachings herein are explained in more detail below on the basis of the schematic drawings. In the figures, the same reference signs are used for elements with essentially the same function, but these elements do not have to be identical in all details. The description of the subjects specified here is not limited to the individual special embodiments. Features of different exemplary embodiments can as far as technically reasonable-be combined with each other in order to form further exemplary embodiments. For example, variations or modifications described with respect to one of the exemplary embodiments may also be applicable to other exemplary embodiments, unless indicated otherwise. In the drawings:

FIG. 1 shows an illustrative block diagram of one exemplary embodiment of a circuit arrangement for monitoring a rechargeable battery cell incorporating teachings of the present disclosure; and

FIG. 2 shows an illustrative block diagram of another exemplary embodiment of a circuit arrangement for monitoring a rechargeable battery cell incorporating teachings of the present disclosure.

### DETAILED DESCRIPTION

Some embodiments of the teachings herein include a method for monitoring a rechargeable battery cell of a rechargeable battery. This first involves a first measurement signal that is representative of a cell voltage of the rechargeable battery cell being received by a circuit arrangement comprising a main monitoring channel and a redundant monitoring channel. The first measurement signal is supplied to the main monitoring channel, which comprises a first analog-to-digital converter (ADC), and to the redundant monitoring channel, which comprises a second ADC. The first ADC performs an analog-to-digital conversion of the first measurement signal and provides a digital first output signal that is representative of a cell voltage of the rechargeable battery cell. The second ADC performs an analog-to-digital conversion of a signal comprising the first measurement signal and provides a digital second output signal.

The first output signal of the main monitoring channel and the second output signal of the redundant monitoring channel are taken as a basis for determining a comparison signal. If the first output signal goes below a specified first voltage value and exceeds a specified second voltage value, the comparison signal is compared with a specified first trigger threshold and, if the comparison signal is greater than the first trigger threshold, a first error signal is provided for an evaluation unit. If, on the other hand, the first output signal is equal to or greater than the specified first voltage value or equal to or less than the second specified voltage value, the comparison signal is compared with a second specified trigger threshold and, if the comparison signal is greater than the second trigger threshold, a second error signal is provided for the evaluation unit. In this case, the first voltage value is greater than the second voltage value and the first trigger threshold has a greater magnitude than the second trigger threshold.

Implementing two different trigger thresholds allows the range of the rechargeable battery to be increased with unchanged hardware.

This exploits the knowledge that, depending on the operating range of the rechargeable battery, the flowing currents and thus the ripple disturbances are different. In a normal operating range of the rechargeable battery, each cell of the rechargeable battery exceeds a lower voltage, which comprises the lowest permissible cell voltage, i.e. a lower critical cell voltage limit, plus a first voltage value, for example approximately 0.1 V, and each cell of the rechargeable battery is below an upper voltage, which comprises a maximum permissible cell voltage, i.e. an upper critical cell voltage limit, minus a second voltage value, for example approximately 0.1 V. High currents flow in the normal operating range of the rechargeable battery and thus major ripple disturbances occur. The trigger threshold is therefore set to a higher level in the normal operating range of the rechargeable battery so that the high ripple disturbances do not lead to a false alarm.

In critical operating ranges, when the rechargeable battery is operated close to the critical cell voltages, where only low charging currents (at the upper cell voltage limit) or low discharge currents (at the lower cell voltage limit) flow and thus only minor ripple disturbances can occur, a lowered trigger threshold is selected.

In some embodiments, the first specified voltage value corresponds to an upper critical cell voltage limit value minus a safety margin voltage value and the second specified voltage value corresponds to a lower critical cell voltage limit value plus a safety margin voltage value.

In some embodiments, a direction of the current flowing into the rechargeable battery cell is taken as a basis for suppressing or ignoring the second error signal.

If the rechargeable battery is operated at or close to the upper cell voltage limit but is being discharged rather than charged, very large currents and thus also large ripple disturbances can occur. Since discharge currents cannot overload the cells at the upper cell voltage limit, however, exceeding of the second trigger threshold can be ignored for the relevant current direction.

If the rechargeable battery is operated at or close to the lower cell voltage limit but is being charged rather than discharged, very large currents and thus also large ripple disturbances can likewise occur. Since charging currents cannot deep discharge the cells at the lower cell voltage limit, however, exceeding of the threshold value can be ignored for the relevant current direction.

In some embodiments, the signal is identical to the first measurement signal, and the second output signal is representative of the cell voltage of the rechargeable battery cell. This permits simple comparison. Common mode errors cannot be detected, however.

In some embodiments, the first ADC of the main monitoring channel and the second ADC of the redundant monitoring channel use an identical reference voltage, provided by a reference voltage source used by both ADCs, for a respective analog-to-digital conversion. The signal comprises a differential signal that is representative of a difference between a supply voltage of the second ADC or the reference voltage and the provided first measurement signal. The second output signal is representative of a level-shifted cell voltage signal. In this case, the determination of the comparison signal on the basis of the first output signal and the second output signal comprises adding the first output signal and the second output signal and, if the level shift of the cell voltage signal is produced by means of the supply voltage, subtracting a setpoint value of the supply voltage of the second ADC and, if the level shift of the cell voltage signal is produced by means of the reference voltage, subtracting the reference voltage.

The use of a common reference voltage permits more cost-effective and space-saving manufacture of the circuit arrangement and an error in the reference voltage can thus be detected. The circuit arrangement therefore also detects common mode errors (common mode errors in the reference voltage) and does not require any further safety mechanism. No further safety mechanism is therefore required.

Some embodiments include a circuit arrangement for monitoring a rechargeable battery cell of a rechargeable battery. The circuit arrangement comprises a main monitoring channel containing first analog-to-digital converter (ADC) and a redundant monitoring channel containing a second ADC. The circuit arrangement has an associated comparison circuit or the circuit arrangement includes the comparison unit.

The circuit arrangement is designed to receive a first measurement signal that is representative of a cell voltage of the rechargeable battery cell. The circuit arrangement is designed to make the first measurement signal available to the main monitoring channel and the redundant monitoring channel. The first ADC is designed to perform an analog-to-digital conversion of the first measurement signal and to provide a first output signal that is representative of a cell voltage of the rechargeable battery cell. The second ADC is designed to perform an analog-to-digital conversion of a signal comprising the first measurement signal and to provide a second output signal.

The comparison unit is designed to determine a comparison signal on the basis of the first output signal of the main monitoring channel and the second output signal of the redundant monitoring channel. The comparison unit is designed so as, if the first output signal is below a specified first voltage value and exceeds a specified second voltage value, to compare the comparison signal with a specified first trigger threshold and, if the comparison signal is greater than the first trigger threshold, to provide a first error signal for an evaluation unit. The comparison unit is furthermore designed so as, if the first output signal is equal to or greater than the specified first voltage value or equal to or less than the second specified voltage value, to compare the comparison signal with a second specified trigger threshold and, if the comparison signal is greater than the second trigger threshold, to provide a second error signal for the evaluation unit.

In this case, the first voltage value is greater than the second voltage value and the first trigger threshold has a greater magnitude than the second trigger threshold.

In some embodiments, the comparison unit is designed to take a provided current measurement signal that is representative of a direction of the current flowing into the rechargeable battery cell as a basis for suppressing output of the second error signal.

In some embodiments, the signal is identical to the first measurement signal, and the second output signal is representative of the cell voltage of the rechargeable battery Cell.

In some embodiments, the first ADC of the main monitoring channel and the second ADC of the redundant monitoring channel are designed to use an identical reference voltage, provided by a reference voltage source, for a respective analog-to-digital conversion. The signal comprises a differential signal that is representative of a difference between a supply voltage of the second ADC or the reference voltage and the provided first measurement signal. The second output signal is representative of a level-shifted cell voltage signal. The determination of the comparison signal on the basis of the first output signal and the second output signal in this case comprises:
adding the first output signal and the second output signal and,
if the level shift of the cell voltage signal is produced by means of the supply voltage, subtracting a setpoint value of the supply voltage of the second ADC and,
if the level shift of the cell voltage signal is produced by means of the reference voltage, subtracting the reference voltage.

Some embodiments include a monitoring system for a rechargeable battery cell. The monitoring system comprises a circuit arrangement according to the first aspect and a control unit designed to take a digital cell voltage signal that is provided by the circuit arrangement and representative of a present cell voltage of the rechargeable battery cell as a basis for specifying for the comparison unit of the respective circuit arrangement the first trigger threshold if the digital cell voltage signal subceeds the specified first voltage value and exceeds the specified second voltage value and the second trigger threshold if the digital cell voltage signal is equal to or greater than the specified first voltage value or if the digital cell voltage signal is equal to or less than the specified second voltage value.

Some embodiments include a rechargeable battery system that comprises a rechargeable battery containing at least one rechargeable battery cell, for each of all or at least some of the rechargeable battery cells a circuit arrangement according to the second aspect and a control unit designed to take a digital measurement signal that is provided by the respective circuit arrangement and representative of a present cell voltage of the respective rechargeable battery cell as a basis for specifying for the comparison unit of the respective circuit arrangement the first trigger threshold if the digital cell voltage signal subceeds the specified first voltage value and exceeds the specified second voltage value and the second trigger threshold if the digital cell voltage signal is equal to or greater than the specified first voltage value or if the digital cell voltage signal is equal to or less than the specified second voltage value.

Some embodiments include a vehicle comprising a rechargeable battery system as described herein.

It is pointed out that, if an element is referred to as being “connected” or “coupled” to another element, the element may be connected or coupled directly to the other element or intermediate elements may be present. In contrast, if an element is referred to as being “connected” or “coupled” “directly” to another element, there are no intermediate elements present. Other expressions used to describe the relationship between elements should be interpreted in the same way (e.g. “between” versus “directly between”, “adjacent” versus “directly adjacent”, etc.).

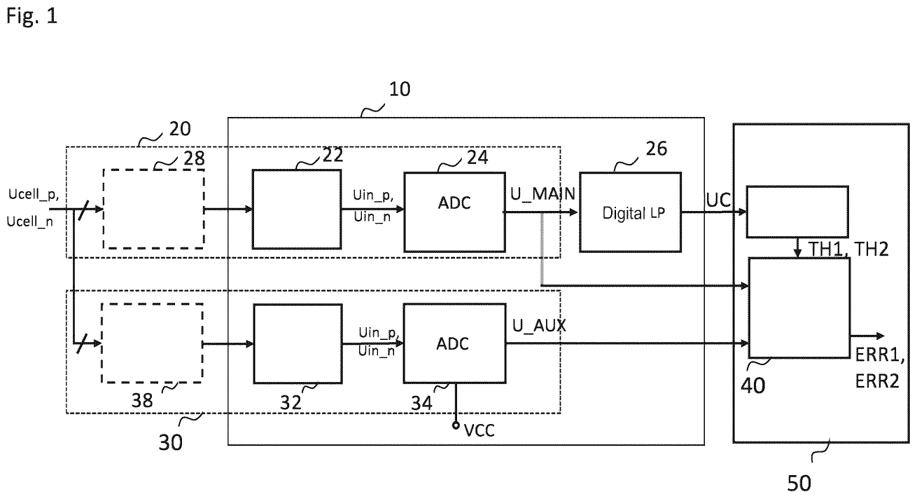

The functions of the circuit arrangement 10 for monitoring a rechargeable battery cell are explained below in connection with FIG. 1, which is a simplified representation of the inventive circuit in which many of the basic components have been omitted for the sake of clarity.

FIG. 1 shows an illustrative block diagram of one exemplary embodiment of a circuit arrangement 10 for monitoring a rechargeable battery cell of a rechargeable battery (rechargeable battery cell and rechargeable battery are not shown in FIG. 1) incorporating teachings of the present disclosure. In some embodiments, the rechargeable battery comprises a plurality of rechargeable battery cells connected in parallel and/or in series. The rechargeable battery is in the form of, for example, a rechargeable traction battery for a vehicle.

The rechargeable battery cell is connected to the circuit arrangement 10, and the input side of the circuit arrangement 10 receives a first cell potential signal Ucell_p and a second cell potential signal Ucell c from the rechargeable battery cell directly or indirectly via a preprocessing unit.

The circuit arrangement 10 comprises a main monitoring channel 20 containing a first analog-to-digital converter, ADC, 24 and a redundant monitoring channel 30 containing a second ADC 34. Furthermore, the circuit arrangement 10 comprises a comparison unit 40, for example. Alternatively, the comparison unit 40 may be part of the evaluation unit 50.

The circuit arrangement 10 is preferably in the form of an integrated circuit in a semiconductor chip. In particular, the semiconductor chip can comprise multiple such circuit arrangements 10, and therefore multiple rechargeable battery cells can be monitored using the semiconductor chip.

The input side of the main monitoring channel 20 comprises an analog first filter 22, for example. The first ADC 24 is connected downstream of the first filter 22. By way of example, the analog first filter 22 of the main monitoring channel 20 is connected directly or indirectly to the rechargeable battery cell. The analog first filter 22 is used for signal processing of the cell potential signals Ucell_p, Ucell_n received from the rechargeable battery cell.

A digital low pass filter 26, for example, is connected downstream of the first ADC 24. By way of example, the output of the digital low pass filter 26 provides a filtered digital cell voltage signal UC, representing the cell voltage of the connected rechargeable battery cell, for an evaluation unit 50. The evaluation unit 50 may be a control unit associated with the circuit arrangement 10, or a higher-level computing unit.

The input side of the redundant monitoring channel 30 of the circuit arrangement 10 comprises an analog second filter 32, for example. The second ADC 34 is connected downstream of the second filter 32. The analog second filter 32 of the redundant monitoring channel 30 is connected directly or indirectly, for example, to the rechargeable battery cell. The analog second filter 32 is used for signal processing of the cell potential signals Ucell_p, Ucell_n received from the rechargeable battery cell.

In some embodiments, a first discrete hardware filter 28 and a second discrete hardware filter 38 are connected upstream of the circuit arrangement 10, the first discrete hardware filter 28 being connected upstream of the first filter 22 of the main monitoring path 20 and the second discrete hardware filter 38 being connected upstream of the second filter 32 of the redundant monitoring path.

The input of the first ADC 24 has a first input terminal for receiving a first measurement signal Uin_p representative of a potential at a positive pole of the rechargeable battery cell and a second input terminal for receiving a second measurement signal Uin_n representative of a potential at a negative pole of the rechargeable battery cell.

The first ADC 24 comprises a first level converter, for example. The first level converter is designed to form a first cell potential difference between the first measurement signal Uin_p and the second measurement signal Uin_n. The first cell potential difference can also be referred to as cell voltage Ucell.

The first ADC 24 furthermore comprises a converter unit designed to carry out the actual analog-to-digital conversion of the cell voltage Ucell and to provide a digital first output signal U_MAIN at the output of the converter unit.

The input of the second ADC 34 has a first input terminal for receiving a first measurement signal Uin_p representative of a potential at a positive pole of the rechargeable battery cell and a second input terminal for receiving a second measurement signal Uin_n representative of a potential at a negative pole of the rechargeable battery cell.

The second ADC 34 comprises a first level converter, for example. The first level converter is designed to form a first cell potential difference between the first measurement signal Uin_p and the second measurement signal Uin_n. The first cell potential difference can also be referred to as cell voltage Ucell.

The first ADC 34 furthermore comprises a converter unit designed to carry out the actual analog-to-digital conversion of the cell voltage Ucell and to provide a digital second output signal U_AUX at the output of the converter unit.

Thus, the first ADC 24 and the second ADC 34 receive the first measurement signal, which is representative of the cell voltage of the rechargeable battery cell. The first ADC 24 and the second ADC 34 each carry out an analog-to-digital conversion of the first measurement signal and provide the first output signal U_MAIN or the second output signal U_AUX at their output. To check whether the first ADC 24 is functioning correctly, the two output signals U_MAIN, U_AUX are compared with each other. For example, a comparison signal is determined that represents a difference between the two output signals U_MAIN, U_AUX.

A further step involves checking whether the comparison signal meets a criterion so that an error can be assumed. That is to say that if, for example, the comparison signal representing the difference between the two output signals U_MAIN, U_AUX exceeds a trigger threshold, an error is detected.

However, since disturbances, more precisely ripple disturbances, which are in particular dependent on the currents flowing, can distort the measurement signals, they are taken into account when selecting the trigger threshold.

Therefore, if the first output signal U_MAIN subceeds a specified first voltage value and exceeds a specified second voltage value, the comparison signal is compared with a specified first trigger threshold TH1, the first voltage value representing a critical upper cell voltage minus a margin value, for example equal to 0.1 V, and the second voltage value representing a critical lower cell voltage plus another margin value, for example equal to 0.1 V. If the comparison signal is greater than the first trigger threshold TH1, a first error signal ERR1 is provided for an evaluation unit 50.

If, on the other hand, the first output signal U_MAIN is equal to or greater than the specified first voltage value or equal to or less than the second specified voltage value, the comparison signal is compared with a second specified trigger threshold TH2 and, if the comparison signal is greater than the second trigger threshold TH2, a second error signal ERR2 is provided for the evaluation unit 50.

The first trigger threshold TH1 has a magnitude of 25 mV, for example, and the second trigger threshold TH2 has a magnitude of 12 mV. This results in a range gain of 26 mV for a defined battery size.

In some embodiments, the second error signal ERR2 is suppressed if the rechargeable battery is operated at or close to the upper cell voltage limit but is being discharged rather than charged. Furthermore, the second error signal ERR2 is suppressed if the rechargeable battery is operated at or close to the lower cell voltage limit but is being charged rather than discharged.

In some embodiments, the evaluation unit 50 may send information to the comparison unit 40 that specifies a current direction. The comparison unit 40 can thus immediately mask the errors if the current direction is not critical. By way of example, the evaluation unit 50 can send an additional flag to the comparison unit 40.

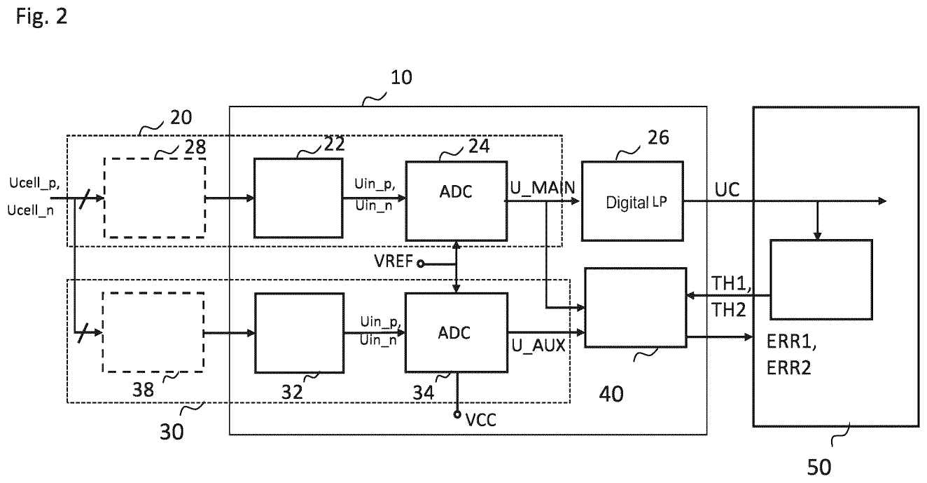

FIG. 2 shows an illustrative block diagram of another exemplary embodiment of the circuit arrangement 10 for monitoring a rechargeable battery cell of a rechargeable battery incorporating teachings of the present disclosure. In contrast to the circuit arrangement 10 shown in FIG. 1, the first ADC 24 and the second ADC 34 use the same reference voltage source.

Furthermore, the second ADC 34 in FIG. 2 comprises a second level converter. The second level converter is designed to form a second cell potential difference between the second measurement signal Uin_n and the first measurement signal Uin_p, the second measurement signal Uin_n forming the minuend and the first measurement signal Uin_p forming the subtrahend. The second level converter is furthermore designed to provide a differential signal Udiff for the second ADC 34 by adding the supply voltage VCC of the second ADC 34 and the second cell potential difference.

In some embodiments, the second level converter is designed to provide the differential signal Udiff for the second ADC 34 by adding a reference voltage VREF, which the two ADCs 24, 34 use for the analog-to-digital conversion, and the second cell potential difference. The second ADC 34 comprises a converter unit designed to carry out the actual analog-to-digital conversion of the differential signal Udiff and to provide the second output signal U_AUX, which in this case is representative of a level-shifted cell voltage signal, at the output of the converter unit.

The converter units of the first ADC 24 and the second ADC 34 can be in the same or different form. In particular, the second ADC 34 can have a lower resolution and/or a longer settling time, as it is sufficient for the comparison to take place only at certain intervals of time. This permits cost-effective implementation and the required reliability can still be guaranteed.

The first ADC 24 and the second ADC 34 are designed to carry out the analog-to-digital conversion of the cell voltage Ucell or the differential signal Udiff on the basis of a reference voltage VREF that is the same for both ADCs 24, 34.

The comparison unit 40 of the circuit arrangement 10 is designed to determine a respective comparison value according to a specified comparison function on the basis of the digital first cell voltage signal U_MAIN and the digital level-shifted second output signal U_AUX.

The comparison function comprises, if the supply voltage VCC is used for the level shift for the second ADC 34, in particular the sum of the digital first output signal U_MAIN and the digital level-shifted second output signal U_AUX minus setpoint value VCC_set of the supply voltage of the second ADC 34.

The digital comparison mechanism in each case thus delivers, as a result, the comparison values

U_delta=U_MAIN+U_AUX−VCC Eq. (1a)

If the reference voltage VREF is used for the level shift for the second ADC 34, the comparison function comprises in particular the sum of the first output signal U_MAIN and the second output signal U_AUX minus the reference voltage VREF. In this case, the digital comparison mechanism in each case delivers, as a result, the comparison values

U_delta=U_MAIN+UAUX−VREF Eq. (1b)

The first ADC 24 and second ADC 34 use the same reference voltage VREF. In the event of the reference voltage VREF deviating upwards by 10% due to an error, the first ADC 24 determines, for the rechargeable battery cell, a cell voltage of

U_MAIN=1.1*Ucell Eq. (2)

and the second ADC 34 determines, when the supply voltage VCC is used for the level shift, a level-shifted cell voltage of

U_AUX=1.1*VCC_act−1.1*Ucell, Eq. (3a)

wherein Ucell is the measured cell voltage of the rechargeable battery cell and VCC_act is the actual value or real value of the supply voltage.

When the reference voltage VREF is used for the level shift, the second ADC 34 determines the level-shifted cell voltage

U_AUX=1.1*VREF−1.1*Ucell. Eq. (3b).

If the supply voltage VCC is used for the level shift in the second ADC 34 and assuming that the setpoint value VCC_set and the actual value VCC_act of the supply voltage are the same, with

VCC_set=VCC_act=VCC, Eq. (4),

the comparison unit 40 ascertains a comparison value of

U_delta=U_MAIN+U_AUX−VCC=0.1*VCC Eq. (5a).

In the case of a supply voltage of, for example, VCC=5 V, this corresponds to 0.5 V.

When the reference voltage VREF is used for the level shift by the second ADC 34, the comparison value results in:

U_delta=U_MAIN+U_AUX−VREF=0.1*VREF Eq. (5b).

The respective comparison value is then compared with the first trigger threshold TH1 or the second trigger threshold TH2 as described in connection with FIG. 1.

The trigger thresholds TH1, TH2 are specified by the evaluation unit 50, for example. The evaluation unit 50 is designed to take a digital cell voltage signal UC that is provided by the circuit arrangement 10 and representative of a present cell voltage of the rechargeable battery cell as a basis for specifying for the comparison unit 40 the first trigger threshold TH1 or the second trigger threshold TH2. In particular, if the digital cell voltage signal UC subceeds the specified first voltage value and exceeds the second voltage value, the first trigger threshold TH1 is specified. If the digital cell voltage signal UC is equal to or greater than the specified first voltage value, the second trigger threshold TH2 is specified. If the digital cell voltage signal UC is equal to or less than the specified second voltage value, the second trigger threshold TH2 is likewise specified.

### LIST OF REFERENCE SIGNS

10 circuit arrangement
20 main monitoring channel
22 analog first filter
24 first ADC
26 digital filter
30 redundant monitoring channel
32 analog second filter
34 second ADC
40 comparison unit
50 evaluation unit
ERR1 first error signal
ERR2 second error signal
TH1 first trigger threshold
TH2 second trigger threshold
U_MAIN first output signal
U_AUX second output signal
UC digital cell voltage signal

What is claimed is:

1. A method for monitoring a rechargeable battery cell of a rechargeable battery, method comprising:
receiving a first measurement signal that is representative of a cell voltage of the rechargeable battery cell s by a circuit arrangement comprising a main monitoring channel and a redundant monitoring channel;
supplying the first measurement signal to a main monitoring channel-having a first analog-to-digital converter (ADC), and to a redundant monitoring channel having a second ADC;
performing an analog-to-digital conversion of the first measurement signal using the first ADC and viding a first output signal representative of a cell voltage of the rechargeable battery cell;
performing an analog-to-digital conversion of a signal comprising the first measurement signal using the second ADC and oviding a second output signal;
determining a comparison signal based on the first output signal and the second output signal;
if the first output signal is below a specified first voltage value and exceeds a specified second voltage value, comparing the comparison signal to a specified first trigger threshold and, if the comparison signal is greater than the first trigger threshold providing a first error signal to an evaluation unit; and,
if the first output signal is equal to or greater than the specified first voltage value or equal to or less than the second specified voltage value, comparing the comparison signal to a second specified trigger threshold and, if the comparison signal is greater than the second trigger threshold providing a second error signal the evaluation unit;
wherein the first voltage value is greater than the second voltage value and the first trigger threshold, has a greater magnitude than the second trigger threshold.

2. The method as claimed in claim 1, wherein the first specified voltage value corresponds to a critical upper cell voltage value minus a safety margin voltage value and the second specified voltage value corresponds to a critical lower cell voltage value plus a safety margin voltage value.

3. The method as claimed in claim 1, further comprising considering a direction of the current flowing into the rechargeable battery cell as a basis for suppressing or ignoring the second error signal

4. The method as claimed in claim 1, wherein the signal is identical to the first measurement signal, and the second output signal represents the cell voltage of the rechargeable battery cell.

5. The method as claimed in claim 1, wherein;
the first ADC and the second ADC use an identical reference voltage, provided by a reference voltage source for a respective analog-to-digital conversion;
the signal comprises a differential signal representative of a difference between a supply voltage of the second ADC or the reference voltage and the provided first measurement signal, and the second output signal represents a level-shifted cell voltage signal, and
determining the comparison signal comprises
adding the first output signal and the second output signal andy
if the level shift of the cell voltage signal is produced by means of the supply voltage, subtracting a setpoint value of the supply voltage of the second ADC; and,
if the level shift of the cell voltage signal is produced by means of the reference voltage, subtracting the reference voltage.

6. A circuit arrangement for monitoring a rechargeable battery cell of a rechargeable battery, the arrangement comprising:
a main monitoring channel having a first analog-to-digital converter (ADC), and a redundant monitoring channel containing a second ADC, and an associated comparison unit;
wherein the arrangement receives a first measurement signal representative of a cell voltage of the rechargeable battery cell and at the main monitoring channel and the redundant monitoring channel;
the first ADC performs an analog-to-digital conversion of the first measurement signal and provides a first output signal representative of a cell voltage of the rechargeable battery cell;
the second ADC performs an analog-to-digital conversion of a signal comprising the first measurement signal and provides a second output signal; the comparison unit determines a comparison signal based on the first output signal and the second output signal; and
if the first output signal subceeds a specified first voltage value and exceeds a specified second voltage value, compares the comparison signal with a specified first trigger threshold and, if the comparison signal is greater than the first trigger threshold, provides a first error signal to an evaluation unit, and,
if the first output signal is equal to or greater than the specified first voltage value or equal to or less than the second specified voltage value, compares the comparison signal with a second specified trigger threshold and, if the comparison signal is greater than the second trigger threshold, provides a second error signalfor the evaluation unit;
wherein the first voltage value is greater than the second voltage value and the first trigger threshold has a greater magnitude than the second trigger threshold.

7. The circuit arrangement as claimed in claim 6, wherein the comparison unit is takes a provided current measurement signal that is representative of a direction of the current flowing into the rechargeable battery cell as a basis for suppressing output of the second error signal.

8. The circuit arrangement as claimed in claim 6, wherein:
the signal is identical to the first measurement signal, and
the second output signal represents a cell voltage of the rechargeable battery cell.

9. The circuit arrangement as claimed in claim 6, wherein:
the first ADC and
the second ADC use an identical reference voltage, provided by a reference voltage source, for a respective analog-to-digital conversion;
the signal comprises a differential signal representative of a difference between a supply voltage of the second ADC or a reference voltage and the provided first measurement signal; and
the comparison signal comprises
adding the first output signal and the second output signal and,
if the level shift of the cell voltage signal is produced by means of the supply voltage, subtracting a setpoint value of the supply voltage of the second ADC; and,
if the level shift of the cell voltage signal is produced by means of the reference voltage, subtracting the reference voltage.

10. A monitoring system for a rechargeable battery cell, the system comprising:
main monitoring channel having a first analog-to-digital converter (ADC), a redundant monitoring channel containing a second ADC, and an associated comparison unit;
wherein the arrangement receives a first measurement signal representative of a cell voltage of the rechargeable battery cell and at the main monitoring channel and the redundant monitoring channel;
the first ADC performs an analog-to-digital conversion of the first measurement signal and provides a first output signal representative of a cell voltage of the rechargeable battery cell;
the second ADC performs an analog-to-digital conversion of a signal comprising the first measurement signal and provides a second output signal;
the comparison unit determines a comparison signal based on the first output signal and the second output signal; and
if the first output signal subceeds a specified first voltage value and exceeds a specified second voltage value, compares the comparison signal with a specified first trigger threshold and, if the comparison signal is greater than the first trigger threshold, provides a first error signal to an evaluation unit, and,
if the first output signal is equal to or greater than the specified first voltage value or equal to or less than the second specified voltage value, compares the comparison signal with a second specified trigger threshold and, if the comparison signal is greater than the second trigger threshold, provides a second error signal for the evaluation unit;
wherein the first voltage value is greater than the second voltage value and the first trigger threshold has a greater magnitude than the second trigger threshold; and
a control unit take a digital measurement signal provided by the circuit arrangement representing a present cell voltage of the rechargeable battery cell as a basis for specifying:
the first trigger threshold if the digital cell voltage signal UC subceeds the specified first voltage value and exceeds the second voltage value, and
the second trigger threshold if the digital cell voltage signal is equal to or greater than the specified first voltage value; and
the second trigger threshold if the digital cell voltage signal is equal to or less than the specified second voltage value.

11-12. (canceled)
